(19) United States
(12) Patent Application Publication
(10) Pub. No.: US 2026/0086463 A1
(43) Pub. Date: Mar. 26, 2026

(54) METHOD OF MANUFACTURING A PATTERNED PHOTORESIST LAYER OVER A BASE MATERIAL

(71) Applicant: NANYA TECHNOLOGY CORPORATION, NEW TAIPEI CITY (TW)

(72) Inventor: CHENG-WEI YANG, NEW TAIPEI CITY (TW)

(21) Appl. No.: 18/892,904

(22) Filed: Sep. 23, 2024

(51) Int. Cl. G03F 7/40

(52) U.S. Cl. CPC G03F 7/40

(57) ABSTRACT

A method of manufacturing a patterned photoresist layer over a base material and a method of manufacturing a plurality of openings in a base layer are provided. The method includes: providing a base material; forming a photoresist layer over the base material, wherein the photoresist layer includes a negative expansion coefficient material; patterning the photoresist layer to form a first actual pattern having a first critical dimension; and applying an energy to the photoresist layer so that the first actual pattern becomes a second actual pattern, wherein the second actual pattern has a second critical dimension different from the first critical dimension of the first actual pattern.

### TECHNICAL FIELD

The present disclosure relates to a manufacturing method, and more particularly, to a method of manufacturing a patterned photoresist layer over a base material and a method of manufacturing a plurality of openings in a base layer.

### DISCUSSION OF THE BACKGROUND

Semiconductor structures are used in a variety of electronic applications, and the dimensions of semiconductor structures are continuously being scaled down to meet the current application requirements. However, a variety of issues arise during the scaling-down process and impact the final electrical characteristics, quality, cost and yield. Typical memory devices (such as dynamic random access memory (DRAM) devices) include a plurality of openings or trenches formed by using a patterned photoresist layer. As DRAM devices are scaled down and the dimensions and/or pitches of the openings or trenches are getting smaller, the patterned photoresist layer will be a critical concern.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a method of manufacturing a patterned photoresist layer over a base material. The method includes: providing a base material; forming a photoresist layer over the base material, wherein the photoresist layer includes a negative expansion coefficient material; patterning the photoresist layer to form a first actual pattern having a first critical dimension; and applying an energy to the photoresist layer so that the first actual pattern becomes a second actual pattern, wherein the second actual pattern has a second critical dimension different from the first critical dimension of the first actual pattern.

Another aspect of the present disclosure provides a method of manufacturing a patterned photoresist layer over a base material. The method includes: providing a base material; determining a first predetermined pattern; determining a second predetermined pattern according to the first predetermined pattern, wherein a critical dimension of the first predetermined pattern is different from a critical dimension of the second predetermined pattern; forming a photoresist layer over the base material; providing a photomask having a mask pattern corresponding to the second predetermined pattern; patterning the photoresist layer to form a first actual pattern corresponding to the second predetermined pattern through the photomask; and changing the first actual pattern to a second actual pattern corresponding to the first predetermined pattern.

Another aspect of the present disclosure provides method of manufacturing a plurality of openings in a base layer. The method includes: providing a base material including the base layer; forming a photoresist layer over the base material; patterning the photoresist layer to form a first actual pattern; shrinking the first actual pattern to form a second actual pattern; etching the base material to form a plurality of openings by using the second actual pattern; and removing the photoresist layer.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 illustrates, in a flowchart diagram form, a method of manufacturing a plurality of openings in a base layer in accordance with one embodiment of the present disclosure.

FIGS. 2A to 16 illustrate stages of a method of manufacturing a plurality of openings in a base layer in accordance with one embodiment of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only, and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

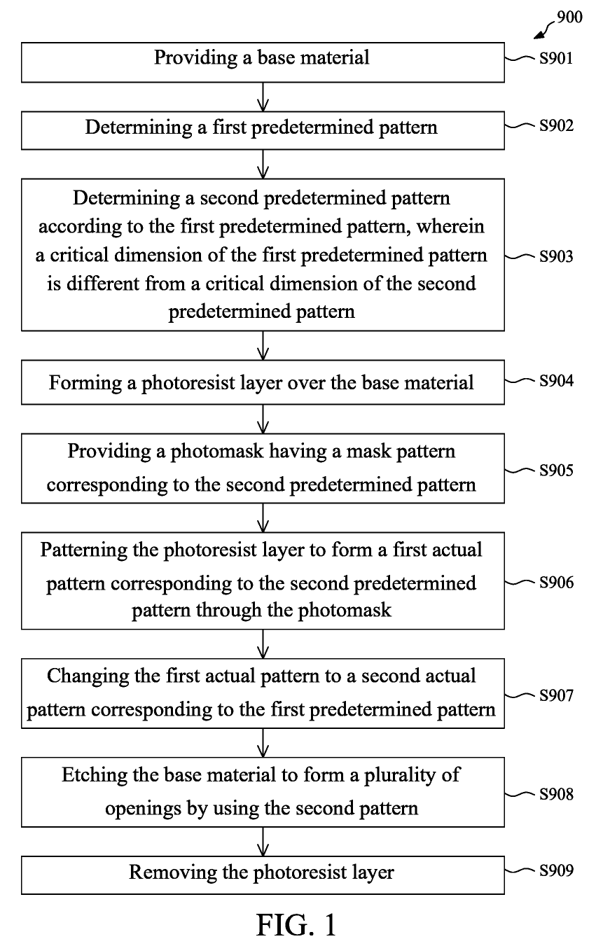

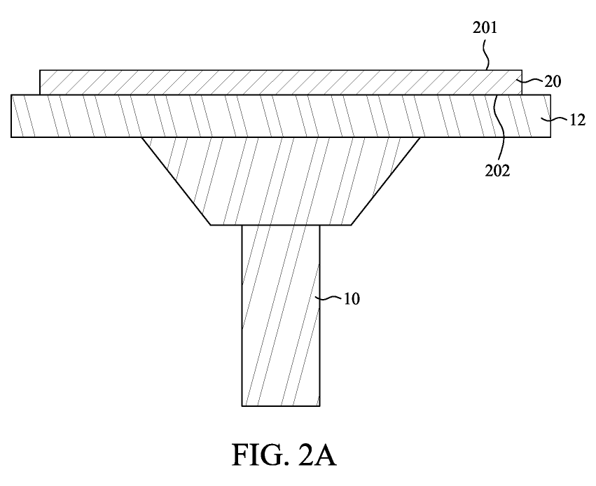

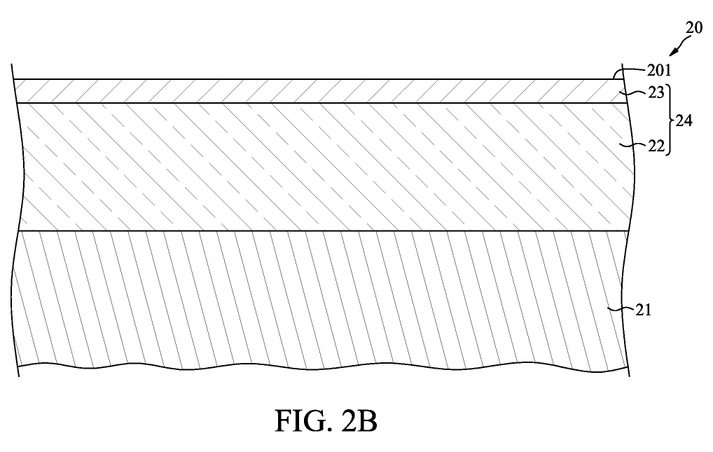

FIG. 1 illustrates, in a flowchart diagram form, a method 900 for manufacturing a plurality of openings 213 in a base layer 21 in accordance with one embodiment of the present disclosure. FIGS. 2A to 16 illustrate stages of a method for manufacturing the plurality of openings 213 in the base layer 21 in accordance with one embodiment of the present disclosure. In some embodiments, FIGS. 2A to 14B illustrate stages of a method for manufacturing a patterned photoresist layer 50 over a base material 20 in accordance with one embodiment of the present disclosure. At least some of these figures have been simplified for a better understanding of the aspects of the present disclosure.

With reference to FIGS. 2A and 2B, at step S901, a base material 20 may be provided or formed on a table 12. FIG. 2A may illustrate a cross-sectional view of a spinning shaft 10 (or a spindle), the table 12 and the base material 20. FIG. 2B may illustrate a partially enlarged view of an area of FIG. 2A. The spinning shaft 10 (or spindle) is connected to the table 12 and is configured to spin or rotate the table 12 and the base material 20 disposed on the table 12. The base material 20 may have a top surface 201 and a bottom surface 202 opposite to the top surface 201. The bottom surface 202 of the base material 20 may be disposed on and may contact the table 12.

In some embodiments, the base material 20 may be a substrate, and may include a dielectric material, such as an oxide material or a nitride material. Alternatively, the base material 20 may be a substrate, and may include, for example, silicon (Si), germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

In some embodiments, the base material 20 may include a base layer 21 and a sacrificial layer 24 disposed on the base layer 21. In some embodiments, the base layer 21 may be a substrate, and may include a dielectric material, such as an oxide material or a nitride material. Alternatively, the base layer 21 may be a substrate, and may include, for example, silicon (Si), germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

In some embodiments, the base layer 21 may be a semiconductor device that includes a circuit, such as a memory cell. In some embodiments, the memory cell may include a dynamic random access memory cell (DRAM cell).

In addition, the base layer 21 may be or include a portion of an integrated circuit (IC) chip that includes various passive and active microelectronic devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or combinations thereof.

The sacrificial layer 24 may include at least one carbon layer 22 on the base layer 21 and at least one antireflective coating (ARC) layer 23 on the carbon layer 22. The number of the carbon layer 22 and the antireflective coating (ARC) layer 23 may not be limited. For example, there may be more than two carbon layers 22 and/or more than two antireflective coating (ARC) layers 23. In some embodiments, the sacrificial layer 24 (including the carbon layer 22 and the base layer 21) may be removed after a formation of a plurality of openings 213 in the base layer 21. In some embodiments, the sacrificial layer 24 (including the carbon layer 22 and the base layer 21) may be omitted.

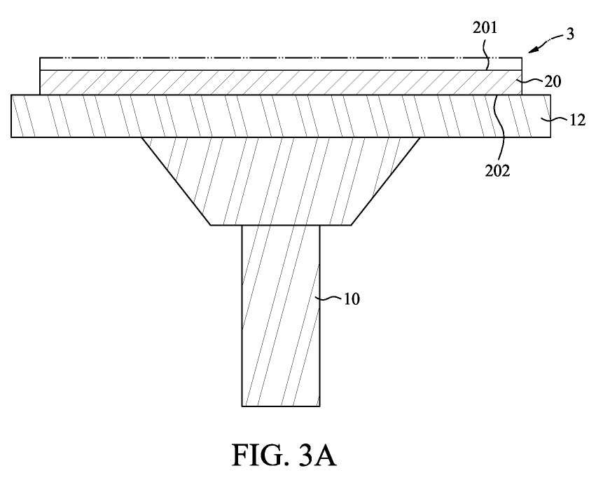

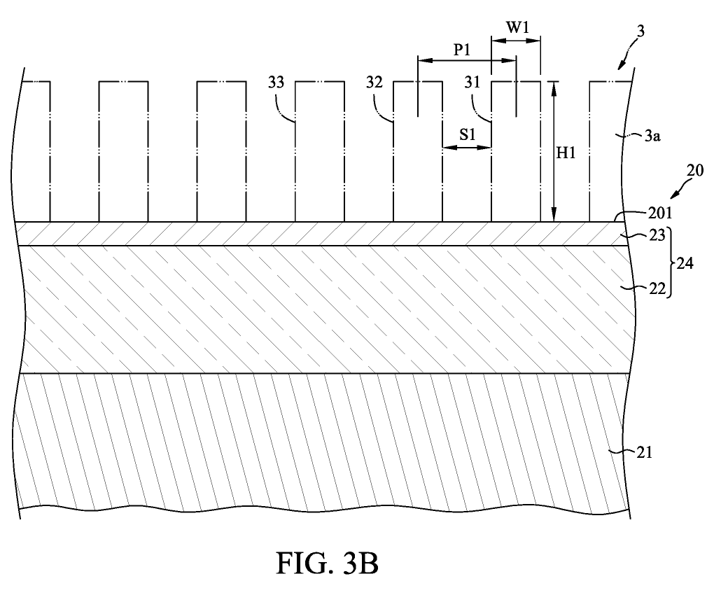

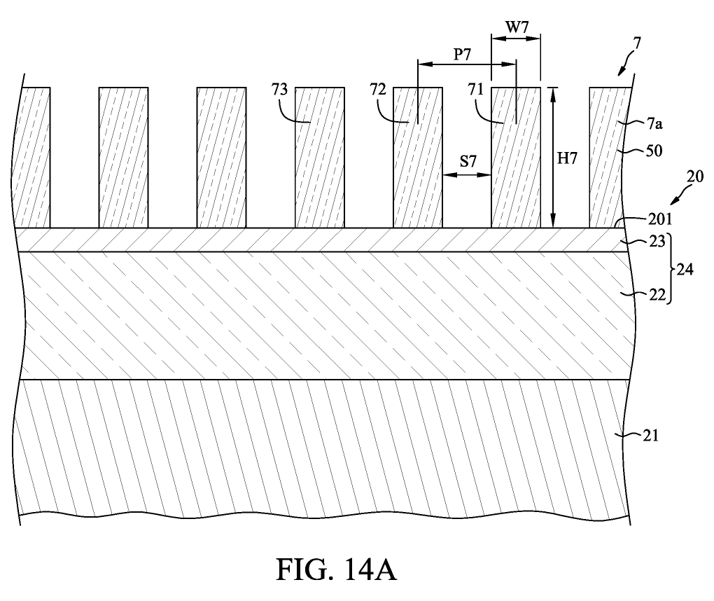

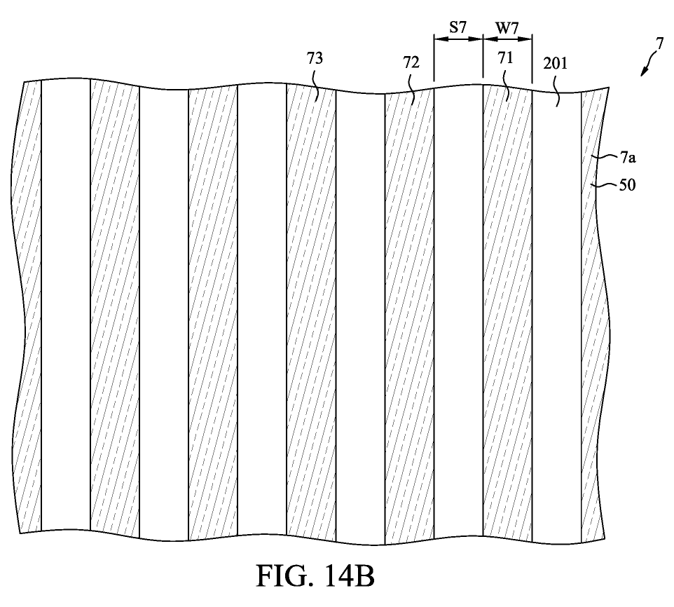

With reference to FIGS. 3A and 3B, at step S902, a first predetermined pattern 3 may be determined. FIG. 3A may illustrate a cross-sectional view of the spinning shaft 10, the table 12, the base material 20 and the first predetermined pattern 3. FIG. 3B may illustrate a partially enlarged view of an area of FIG. 3A. The first predetermined pattern 3 may be an imaginary desired pattern. That is, the first predetermined pattern 3 is a target pattern of the final product (i.e., the final actual patterned photoresist layer 50 (FIG. 14A)). The first predetermined pattern 3 may be designed by a computer program, and is used in the following step. The first predetermined pattern 3 is not an actual pattern of the patterned photoresist layer 50 (FIG. 14A).

Referring to FIG. 3B, the first predetermined pattern 3 may be assumed to be disposed on the top surface 201 of the base material 20, and may include a plurality of predetermined imaginary portions 3a spaced apart from each other. The first predetermined pattern 3 may have a critical dimension. For example, the predetermined imaginary portions 3a may include a first predetermined imaginary portion 31, a second predetermined imaginary portion 32 and a third predetermined imaginary portion 33 assumed to be disposed on the top surface 201 of the base material 20 and spaced apart from each other. The predetermined imaginary portions 3a (including the first predetermined imaginary portion 31, the second predetermined imaginary portion 32 and the third predetermined imaginary portion 33) are line structures parallel with each other from a top view.

The sizes of the predetermined imaginary portions 3a (including the first predetermined imaginary portion 31, the second predetermined imaginary portion 32 and the third predetermined imaginary portion 33) may be substantially equal to each other. However, in other embodiments, the sizes of the predetermined imaginary portions 3a (including the first predetermined imaginary portion 31, the second predetermined imaginary portion 32 and the third predetermined imaginary portion 33) may be different form each other.

The first predetermined imaginary portion 31 may have a first width W1 and a first height H1. A first aspect ratio of the first height H1 to the first width W1 may be greater than 3.0, 3.3, 3.5 or 3.8. For example, the first height H1 may be 130 nm, the first width W1 may be 36 nm, thus, the first aspect ratio may be 3.61. For example, the first height H1 may be 130 nm, the first width W1 may be 35 nm, thus, the first aspect ratio may be 3.71. For example, the first height H1 may be 130 nm, the first width W1 may be 30 nm, thus, the first aspect ratio may be 4.33. As well known in the art, when the first aspect ratio is greater than 3.5, the portions 3a of the first predetermined pattern 3 will readily tilt, lean or shift during a spinning process if the portions 3a of the first predetermined pattern 3 are actual portions of a pattern.

A space S1 (or a gap) may be formed between the first predetermined imaginary portion 31 and the second predetermined imaginary portion 32. A pitch P1 may be formed between the center of the first predetermined imaginary portion 31 and the center of the second predetermined imaginary portion 32. In some embodiments, the space S1 (or a gap) may be substantially equal to the first width W1.

Thus, the critical dimension of the first predetermined pattern 3 may include the first height H1 of one of the plurality of predetermined portions 3a (e.g., the first predetermined imaginary portion 31) of the first predetermined pattern 3, the first width W1 of one of the plurality of predetermined portions 3a (e.g., the first predetermined imaginary portion 31) of the first predetermined pattern 3, the space S1 (or a gap) between most adjacent two of the plurality of predetermined portions 3a (e.g., the first predetermined imaginary portion 31 and the second predetermined imaginary portion 32), and the pitch P1 between the plurality of predetermined portions 3a (e.g., between the center of the first predetermined imaginary portion 31 and the center of the second predetermined imaginary portion 32).

In addition, a width of the second predetermined imaginary portion 32 may be equal to or different from the first width W1. A height of the second predetermined imaginary portion 32 may be equal to or different from the first height H1. Further, a space (or a gap) between the second predetermined imaginary portion 32 and the third predetermined imaginary portion 33 may be equal to or different from the space S1 (or a gap). A pitch between the center of the second predetermined imaginary portion 32 and the center of the third predetermined imaginary portion 33 may be equal to or different from the pitch P1.

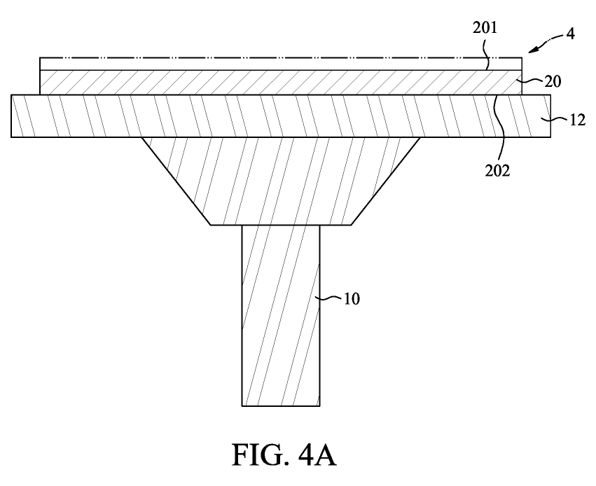

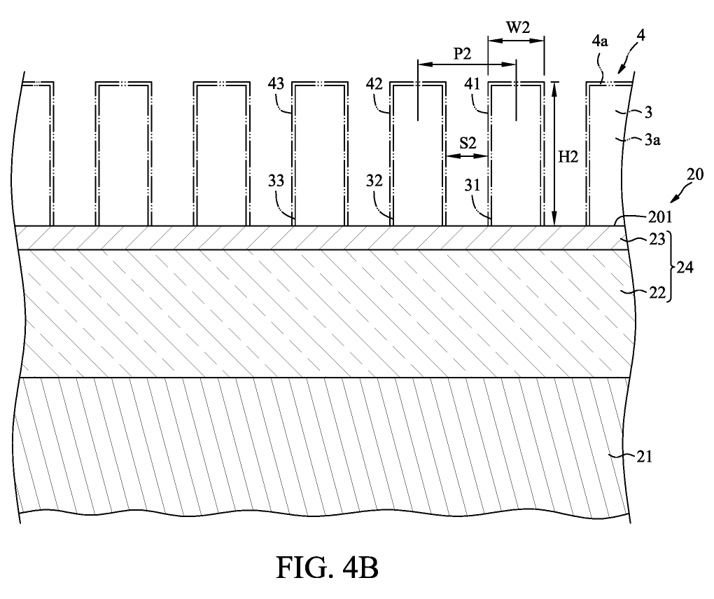

With reference to FIGS. 4A and 4B, at step S903, a second predetermined pattern 4 may be determined according to the first predetermined pattern 3. FIG. 4A may illustrate a cross-sectional view of the spinning shaft 10, the table 12, the base material 20 and the second predetermined pattern 4. FIG. 4B may illustrate a partially enlarged view of an area of FIG. 4A. The second predetermined pattern 4 may be an imaginary temporary pattern. That is, the second predetermined pattern 4 is not a target pattern of the final product (i.e., the final actual patterned photoresist layer 50 (FIG. 14A)). The second predetermined pattern 4 may be designed by a computer program, and is used in the following step. The second predetermined pattern 4 is not an actual pattern of the patterned photoresist layer 50 (FIG. 14A). The second predetermined pattern 4 is enlarged from the first predetermined pattern 3

Referring to FIG. 4B, the second predetermined pattern 4 may be assumed to be disposed on the top surface 201 of the base material 20, and may include a plurality of predetermined imaginary portions 4a spaced apart from each other. The second predetermined pattern 4 may have a critical dimension. For example, the predetermined imaginary portions 4a may include a first predetermined imaginary portion 41, a second predetermined imaginary portion 42 and a third predetermined imaginary portion 43 assumed to be disposed on the top surface 201 of the base material 20 and spaced apart from each other. The predetermined imaginary portions 4a (including the first predetermined imaginary portion 41, the second predetermined imaginary portion 42 and the third predetermined imaginary portion 43) are line structures parallel with each other from a top view.

The sizes of the predetermined imaginary portions 4a (including the first predetermined imaginary portion 41, the second predetermined imaginary portion 42 and the third predetermined imaginary portion 43) may be substantially equal to each other. However, in other embodiments, the sizes of the predetermined imaginary portions 4a (including the first predetermined imaginary portion 41, the second predetermined imaginary portion 42 and the third predetermined imaginary portion 43) may be different form each other.

The first predetermined imaginary portion 41 may have a second width W2 and a second height H2. A second aspect ratio of the second height H2 to the second width W2 may be less than 2.5, 2.6, 2.7, 2.8, 3.0, or 3.5. For example, the second height H2 may be 131 nm, the second width W2 may be 38 nm, thus, the second aspect ratio may be 3.44. For example, the second height H2 may be 132.5 nm, the second width W2 may be 41 nm, thus, the second aspect ratio may be 3.23. For example, the second height H2 may be 132.5 nm, the second width W2 may be 40 nm, thus, the second aspect ratio may be 3.31. For example, the second height H2 may be 137 nm, the second width W2 may be 50 nm, thus, the second aspect ratio may be 2.74. For example, the second height H2 may be 137 nm, the second width W2 may be 49 nm, thus, the second aspect ratio may be 2.80. As well known in the art, when the second aspect ratio is less than 3.5, the portions 4a of the second predetermined pattern 4 will not readily tilt, lean or shift during a spinning process if the portions 4a of the second predetermined pattern 4 are actual portions of a pattern.

A space S2 (or a gap) may be formed between the first predetermined imaginary portion 41 and the second predetermined imaginary portion 42. A pitch P2 may be formed between the center of the first predetermined imaginary portion 41 and the center of the second predetermined imaginary portion 42. In some embodiments, the space S2 (or a gap) may be less than the second width W2.

Thus, the critical dimension of the second predetermined pattern 4 may include the second height H2 of one of the plurality of predetermined portions 4a (e.g., the first predetermined imaginary portion 41) of the second predetermined pattern 4, the second width W2 of one of the plurality of predetermined portions 4a (e.g., the first predetermined imaginary portion 41) of the second predetermined pattern 4, the space S2 (or a gap) between most adjacent two of the plurality of predetermined portions 4a (e.g., the first predetermined imaginary portion 41 and the second predetermined imaginary portion 42), and the pitch P2 between the plurality of predetermined portions 4a (e.g., between the center of the first predetermined imaginary portion 41 and the center of the second predetermined imaginary portion 42).

In addition, a width of the second predetermined imaginary portion 42 may be equal to or different from the second width W2. A height of the second predetermined imaginary portion 42 may be equal to or different from the second height H2. Further, a space (or a gap) between the second predetermined imaginary portion 42 and the third predetermined imaginary portion 43 may be equal to or different from the space S2 (or gap). A pitch between the center of the second predetermined imaginary portion 42 and the center of the third predetermined imaginary portion 43 may be equal to or different from the pitch P2.

In some embodiments, the critical dimension of the first predetermined pattern 3 is different from the critical dimension of the second predetermined pattern 4. For example, the second height H2 of the first predetermined imaginary portion 41 is greater than the first height H1 of the first predetermined imaginary portion 31. The second width W2 of the first predetermined imaginary portion 41 is greater than the first width W1 of the first predetermined imaginary portion 31. However, the pitch P1 between the plurality of predetermined portions 3a of the first predetermined pattern 3 is substantially equal to the pitch P2 between the plurality of predetermined portions 4a of the second predetermined pattern 4.

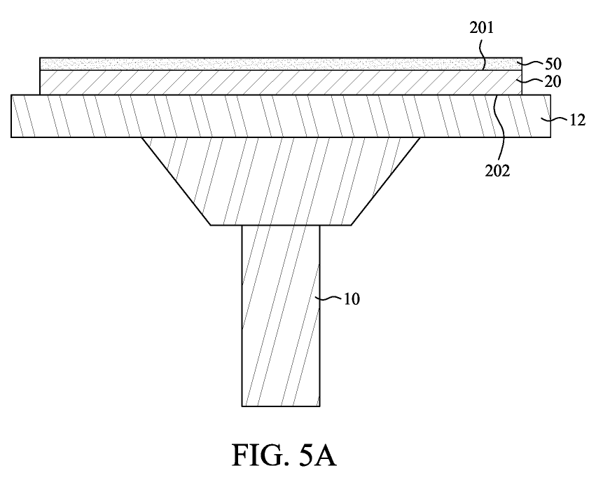

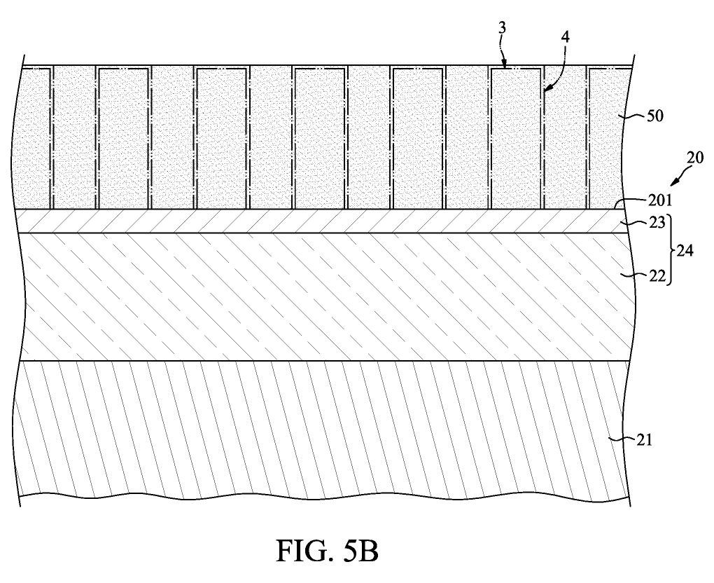

With reference to FIGS. 5A and 5B, at step S904, a photoresist layer 50 may be formed or disposed over the base material 20. FIG. 5A may illustrate a cross-sectional view of the spinning shaft 10, the table 12, the base material 20 and the photoresist layer 50. FIG. 5B may illustrate a partially enlarged view of an area of FIG. 5A.

The photoresist layer 50 may be formed or disposed on the antireflective coating (ARC) layer 23 of the base material 20 by, for example, spin coating. The photoresist layer 50 may include a negative expansion coefficient material. For example, the photoresist layer 50 may have a negative thermal expansion coefficient. In some embodiments, the negative thermal expansion coefficient may be in a range from -3ppm/K to -500ppm/K, such as -3ppm/K to -6ppm/K, -5ppm/K to -10ppm/K, -10ppm/K to -100ppm/K, -100ppm/K to -150ppm/K, -100ppm/K to -200ppm/K, -200ppm/K to -500ppm/K. In some embodiments, if a negative thermal expansion coefficient of a material is -3ppm/K, a shrinkage amount of such material having a length of 1 meter will be 0.3 mm when being heated to 100℃. In some embodiments, the photoresist layer 50 (i.e., the negative expansion coefficient material) may include Zr₂WO₄(PO₄)₂ or ZrW₂O₂.

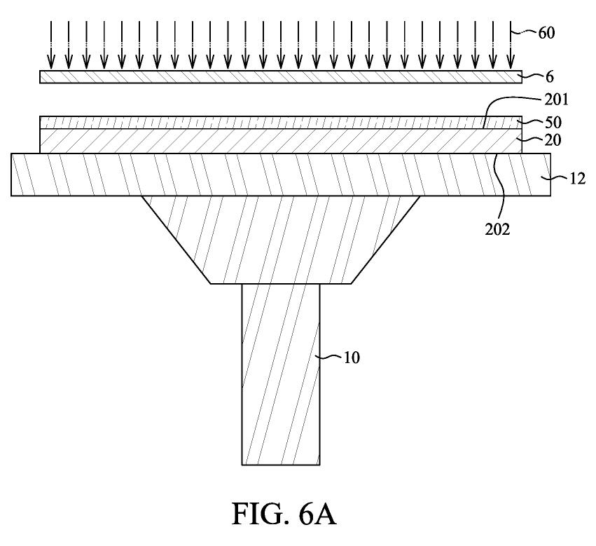

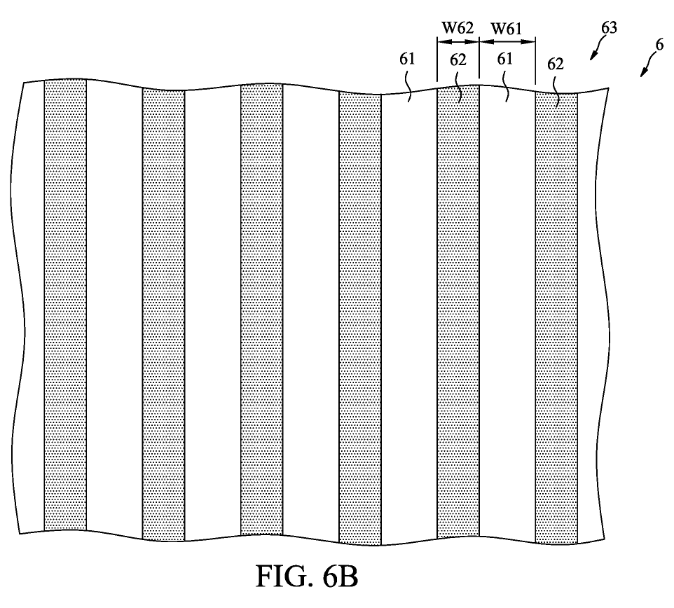

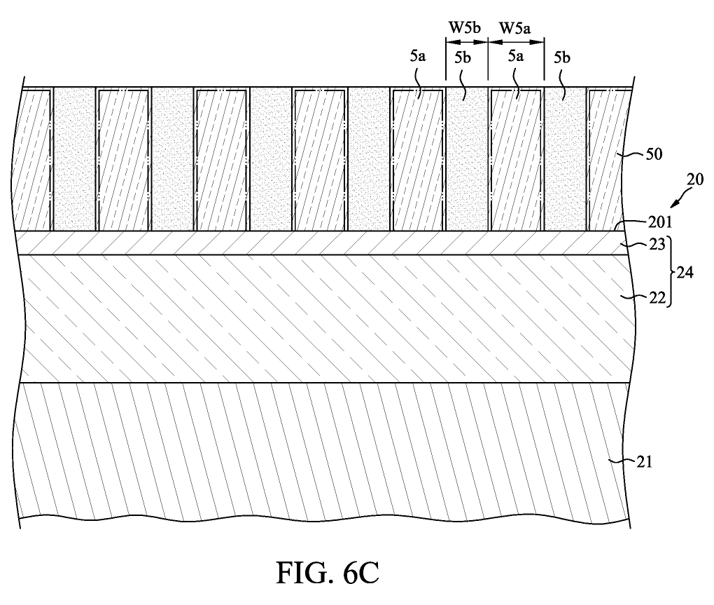

With reference to FIGS. 6A to 10B, the photoresist layer 50 may be patterned to form a first actual pattern 5.

With reference to FIGS. 6A, 6B and 6C, at step S905, a photomask 6 having a mask pattern 63 corresponding to the second predetermined pattern 4 may be provided over the photoresist layer 50. FIG. 6A may illustrate a cross-sectional view of the spinning shaft 10, the table 12, the base material 20, the photoresist layer 50 and the photomask 6. FIG. 6B may illustrate a partially enlarged top view of an area of the photomask 6 of FIG. 6A. FIG. 6C may illustrate a partially enlarged view of an area of FIG. 6A.

As shown in FIG. 6B, the photomask 6 may include a plurality of transparent portions 61 and a plurality of opaque portions 62. The plurality of transparent portions 61 may be spaced apart from each other through the plurality of opaque portions 62. The plurality of opaque portions 62 may be disposed between the plurality of transparent portions 61. The transparent portions 61 and the opaque portions 62 may be in line structures. The transparent portion 61 may have a width W61, which is equal to the second width W2 of the first predetermined imaginary portion 41 of the second predetermined pattern 4. The opaque portion 62 may have a width W62, which is equal to the space S2 (or a gap) between the first predetermined imaginary portion 41 and the second predetermined imaginary portion 42 of the second predetermined pattern 4.

As shown in FIGS. 6A and 6C, an exposure process may be conducted by applying the light 60 passing through the photomask 6. Thus, the photoresist layer 50 is exposed through the photomask 6, and may include a plurality of illuminated portions 5a and a plurality of non-illuminated portions 5b. The illuminated portions 5a may correspond to the transparent portions 61 of the photomask 6, and may react with the light 60. A width W5a of the illuminated portion 5a may be equal to the width W61 of the transparent portion 61 of the photomask 6. Further, the non-illuminated portions 5b may correspond to the opaque portions 62 of the photomask 6, and may not react with the light 60. A width W5b of the non-illuminated portion 5b may be equal to the width W62 of the opaque portion 62 of the photomask 6.

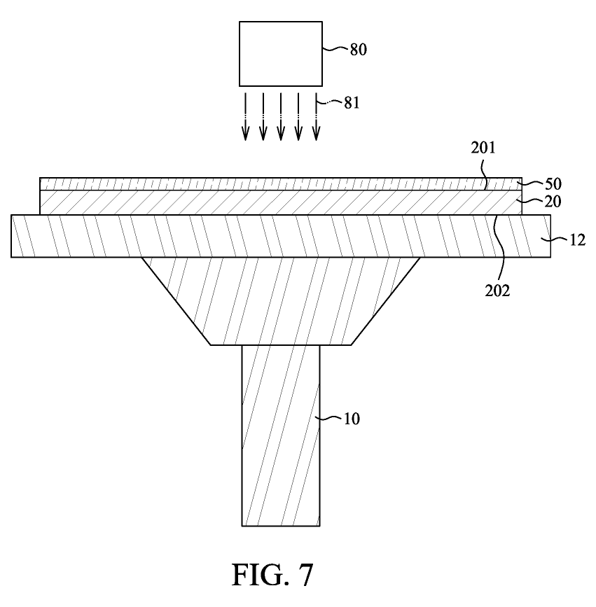

With reference to FIG. 7, a development process may be conducted to the exposed photoresist layer 50. FIG. 7 may illustrate a cross-sectional view of the spinning shaft 10, the table 12, the base material 20, the photoresist layer 50 and a developer supply device 80. A developer 81 may be applied to the exposed photoresist layer 50 by using the developer supply device 80 over the photoresist layer 50. Thus, the photoresist layer 50 may be developed, and the non-illuminated portions 5b may be reacted with the developer 81 and removed by the developer 81. The illuminated portions 5a may remain.

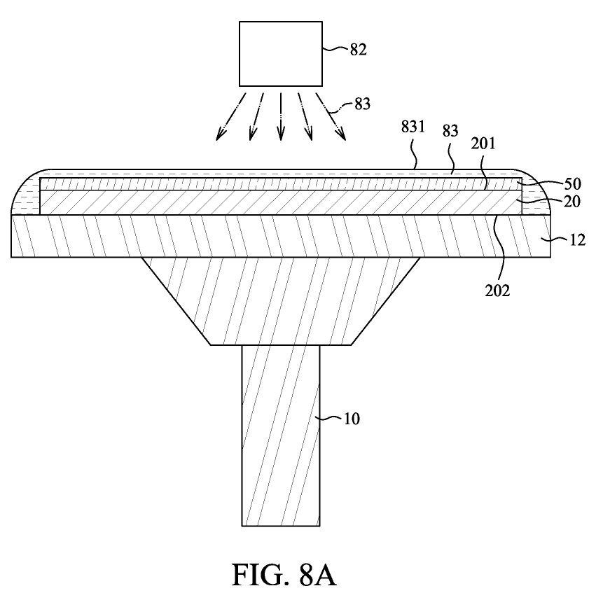

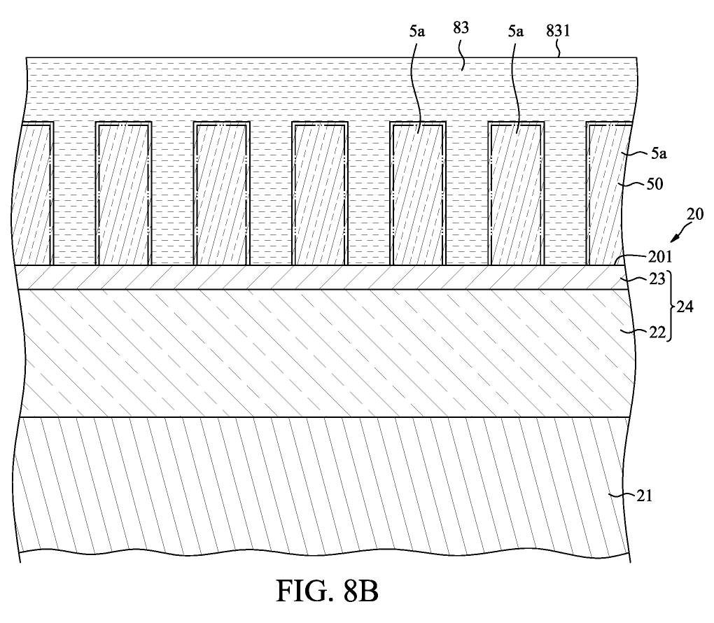

With reference to FIGS. 8A and 8B, a rinsing process may be conducted to the developed photoresist layer 50. FIG. 8A may illustrate a cross-sectional view of the spinning shaft 10, the table 12, the base material 20, the photoresist layer 50 and a rinsing fluid supply device 82. FIG. 8B may illustrate a partially enlarged view of an area of FIG. 8A. A rinsing fluid 83 (e.g., deionized water (DIW)) may be applied to the photoresist layer 50 by using the rinsing fluid supply device 82 over the photoresist layer 50. The rinsing fluid 83 (e.g., deionized water (DIW)) may be used to wash, clean and rinse the photoresist layer 50. The top surface 831 of the rinsing fluid 83 (e.g., deionized water (DIW)) may be higher than the top surface of the photoresist layer 50.

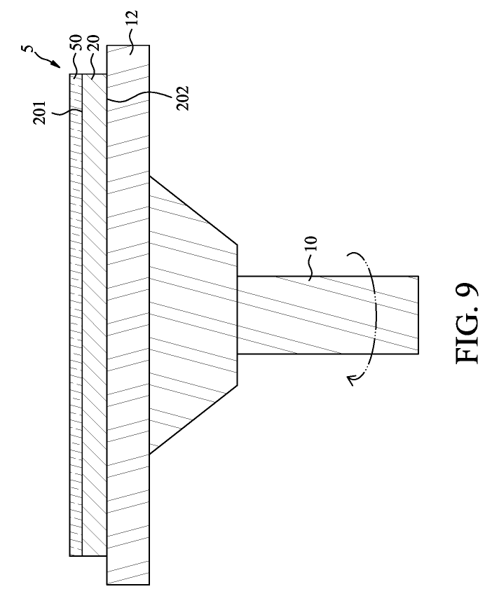

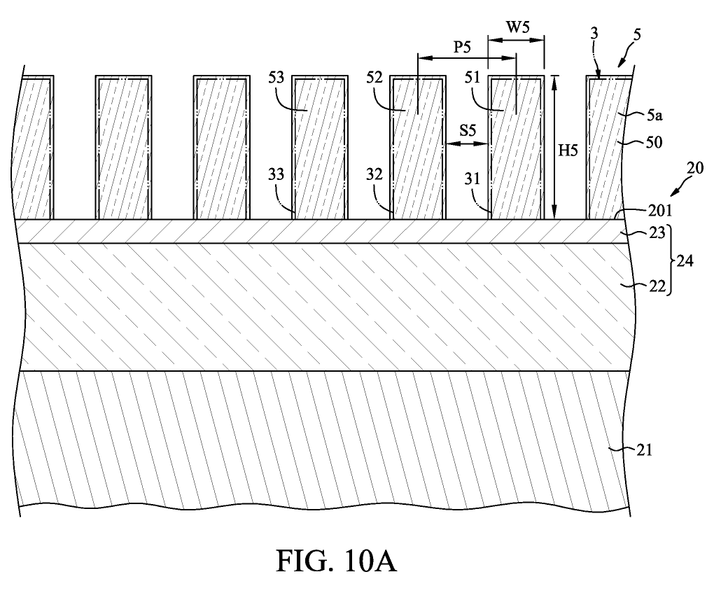

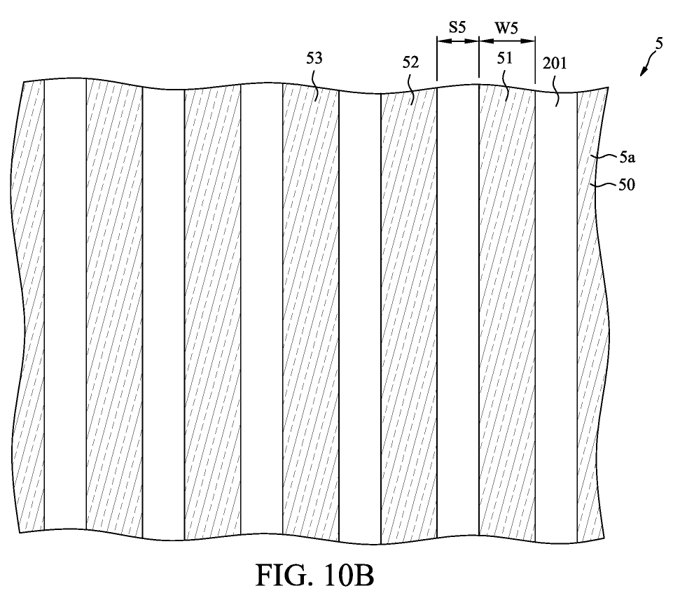

With reference to FIGS. 9, 10A and 10B, at step S906, the spinning shaft 10 (or a spindle) may spin to rotate the table 12, the base material 20 and the photoresist layer 50 disposed on the table 12. FIG. 9 may illustrate a cross-sectional view of the spinning shaft 10, the table 12, the base material 20 and the photoresist layer 50 during spinning. FIG. 10A may illustrate a partially enlarged view of an area of FIG. 9. FIG. 10B may illustrate a partially enlarged top view of FIG. 10A.

That is, the rinsing fluid 83 (e.g., deionized water (DIW)) may be removed by spin drying the photoresist layer 50. Thus, the photoresist layer 50 may be patterned to form a first actual pattern 5 corresponding to the second predetermined pattern 4 through the photomask 6.

Referring to FIG. 10A, the first actual pattern 5 may correspond to the second predetermined pattern 4. The first actual pattern 5 may be an actual temporary pattern. That is, the first actual pattern 5 is not a target pattern of the final product (i.e., the final actual patterned photoresist layer 50 (FIG. 14A)). The first actual pattern 5 may be formed by above-mentioned process, and may be used in the following step.

The first actual pattern 5 may be disposed on the top surface 201 of the base material 20, and may include a plurality of portions 5a (or protrusions or spacers or blocks or segments) spaced apart from each other. The portion 5a may be also referred to as "first portion", "actual portion" or "first actual portion". The portions 5a of the first actual pattern 5 are the illuminated portion 5a of FIG. 6C that remains on the top surface 201 of the base material 20. The first actual pattern 5 may have a first critical dimension. For example, the first actual pattern 5 may include a first portion 51, a second portion 52 and a third portion 53 disposed on the top surface 201 of the base material 20 and spaced apart from each other.

As shown in FIG. 10B, the portions 5a of the first actual pattern 5 (including the first portion 51, the second portion 52 and the third portion 53) are line structures parallel with each other from the top view.

Referring to FIG. 10A, the sizes of the portions 5a (including the first portion 51, the second portion 52 and the third portion 53) may be substantially equal to each other. However, in other embodiments, the sizes of the portions 5a (including the first portion 51, the second portion 52 and the third portion 53) may be different form each other.

The first portion 51 may have a first width W5 and a first height H5. A first aspect ratio of the first height H5 to the first width W5 may be less than 2.5, 2.6, 2.7, 2.8, 2.9 or 3.0. For example, the first height H5 may be 131 nm, the first width W5 may be 38 nm, thus, the first aspect ratio may be 3.44. For example, the first height H5 may be 132.5 nm, the first width W5 may be 41 nm, thus, the first aspect ratio may be 3.23. For example, the first height H5 may be 132.5 nm, the first width W5 may be 40 nm, thus, the first aspect ratio may be 3.31. For example, the first height H5 may be 137 nm, the first width W5 may be 50 nm, thus, the first aspect ratio may be 2.74. For example, the first height H5 may be 137 nm, the first width W5 may be 49 nm, thus, the first aspect ratio may be 2.80. Since the first aspect ratio is less than 3.5, the portions 5a of the first actual pattern 5 will not readily tilt, lean or shift during a spinning process.

A first space S5 (or a gap) may be formed between the first portion 51 and the second portion 52. A first pitch P5 may be formed between the center of the first portion 51 and the center of the second portion 52. In some embodiments, the first space S5 (or a gap) may be less than the first width W5. The first width W5 may be greater than the first space S5 (or a gap).

Thus, the first critical dimension of the first actual pattern 5 may include the first height H5 of one of the plurality of portions 5a (e.g., the first portion 51) of the first actual pattern 5, the first width W5 of one of the plurality of portions 5a (e.g., the first portion 51) of the first actual pattern 5, the first space S5 (or a gap) between most adjacent two of the plurality of portions 5a (e.g., the first portion 51 and the second portion 52), and the first pitch P5 between the plurality of portions 5a (e.g., between the center of the first portion 51 and the center of the second portion 52).

For example, the first height H5 of the first portion 51 of the first actual pattern 5 may be substantially equal to the second height H2 of the first predetermined imaginary portion 41 of the second predetermined pattern 4. The first width W5 of the first portion 51 of the first actual pattern 5 may be substantially equal to the second width W2 of the first predetermined imaginary portion 41 of the second predetermined pattern 4. The first space S5 (or a gap) of the first actual pattern 5 may be substantially equal to the space S2 (or a gap) of the second predetermined pattern 4. The first pitch P5 of the first actual pattern 5 may be substantially equal to the pitch P2 of the second predetermined pattern 4.

In addition, a width of the second portion 52 may be equal to or different from the first width W5. A height of the second portion 52 may be equal to or different from the first height H5. Further, a space (or a gap) between the second portion 52 and the third portion 53 may be equal to or different from the first space S5 (or gap). A pitch between the center of the second portion 52 and the center of the third portion 53 may be equal to or different from the first pitch P5.

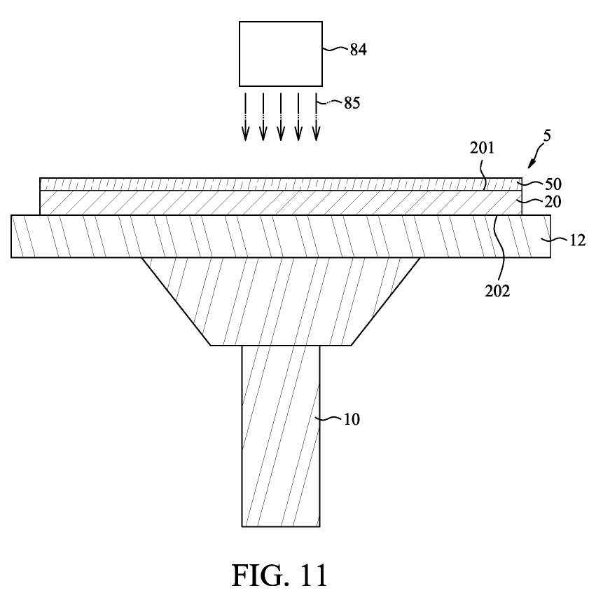

With reference to FIG. 11, an interfacial agent 85 such as a low surface tension liquid or a hydrophobic liquid may be applied to the photoresist layer 50 by using an interfacial agent supply device 84 over the photoresist layer 50. FIG. 11 may illustrate a cross-sectional view of the spinning shaft 10, the table 12, the base material 20, the photoresist layer 50 and the interfacial agent supply device 84. The interfacial agent 85 may be prevent the portions 5a of the first actual pattern 5 from tilting, leaning or shifting.

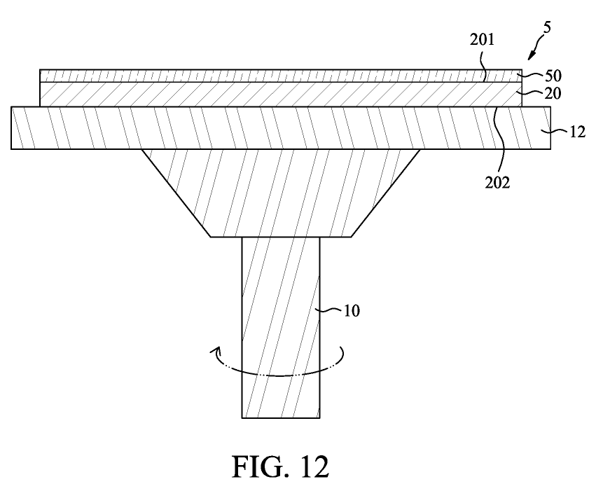

With reference to FIG. 12, the spinning shaft 10 (or a spindle) may spin to rotate the table 12, the base material 20 and the photoresist layer 50 disposed on the table 12. FIG. 12 may illustrate a cross-sectional view of the spinning shaft 10, the table 12, the base material 20 and the photoresist layer 50 during spinning. Thus, the interfacial agent 85 may be removed by spin drying the photoresist layer 50.

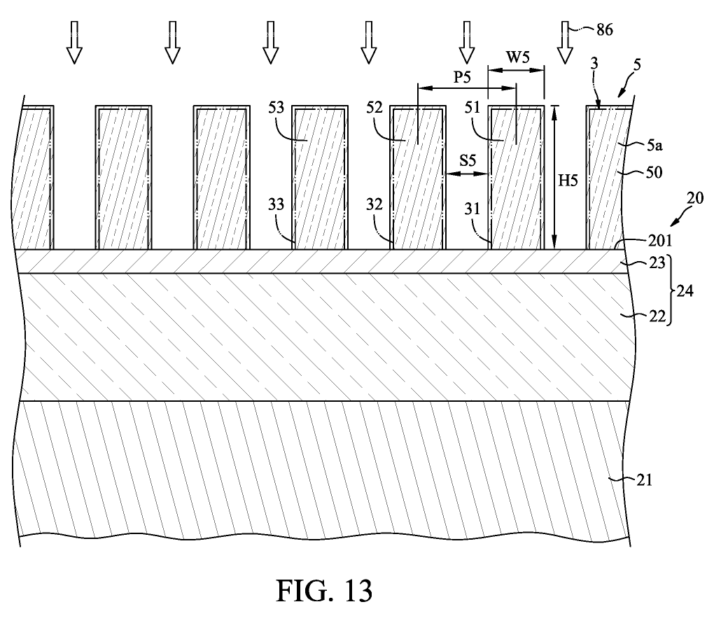

With reference to FIGS. 13, 14A, 14B, at step S907, an energy 86 may be applied to the photoresist layer 50 so that the first actual pattern 5 becomes a second actual pattern 7. That is, the first actual pattern 5 may be changed to the second actual pattern 7. The second pattern 7 has a second critical dimension different from the first critical dimension of the first pattern 5. FIG. 13 may illustrate a partially enlarged cross-sectional view of the base material 20 and the photoresist layer 50 during a heating process. FIG. 14A may illustrate a partially enlarged cross-sectional view of the base material 20 and the photoresist layer 50 after the heating process. FIG. 14B may illustrate a partially enlarged top view of FIG. 14A.

In some embodiments, the energy 86 may be thermal energy. Thus, the step of applying the energy 86 to the photoresist layer 50 may include heating the photoresist layer 50 to a temperature of 100 ℃ to 120 ℃. As a result, the first actual pattern 5 may be changed to the second actual pattern 7. For example, the second actual pattern 7 may shrink from the first actual pattern 5. The second actual pattern 7 may be formed by shrinking the first actual pattern 5.

In some embodiments, the second actual pattern 7 may correspond to the first predetermined pattern 3. The second actual pattern 7 may be a desired pattern. That is, the second actual pattern 7 is a final actual pattern of the photoresist layer 50. The second actual pattern 7 may be used in the following etching step.

Referring to FIG. 14A, the second actual pattern 7 may be disposed on the top surface 201 of the base material 20, and may include a plurality of portions 7a (or protrusions or spacers or blocks or segments) spaced apart from each other. The second actual pattern 7 may have a second critical dimension. For example, the portions 7a may include a first portion 71, a second portion 72 and a third portion 73 disposed on the top surface 201 of the base material 20 and spaced apart from each other. The portion 7a may be also referred to as "second portion", "actual portion" or "second actual portion".

As shown in FIG. 14B, the portions 7a of the second actual pattern 7 (including the first portion 71, the second portion 72 and the third portion 73) are line structures parallel with each other from the top view.

Referring to FIG. 14A, the sizes of the portions 7a (including the first portion 71, the second portion 72 and the third portion 73) may be substantially equal to each other. However, in other embodiments, the sizes of the portions 7a (including the first portion 71, the second portion 72 and the third portion 73) may be different form each other.

The first portion 71 may have a second width W7 and a second height H7. A second aspect ratio of the second height H7 to the second width W7 may be greater than 3.0, 3.3, 3.5 or 3.8. For example, the second height H7 may be 130 nm, the second width W7 may be 36 nm, thus, the second aspect ratio may be 3.61. For example, the second height H7 may be 130 nm, the second width W7 may be 35 nm, thus, the second aspect ratio may be 3.71. For example, the second height H7 may be 130 nm, the second width W7 may be 30 nm, thus, the first aspect ratio may be 4.33.

A second space S7 (or a gap) may be formed between the first portion 71 and the portion 72. A second pitch P7 may be formed between the center of the first portion 71 and the center of the second portion 72. In some embodiments, the second space S7 (or a gap) may be substantially equal to the second width W7.

Thus, the second critical dimension of the second actual pattern 7 may include the second height H7 of one of the plurality of portions 7a (e.g., the first portion 71) of the second actual pattern 7, the second width W7 of one of the plurality of portions 7a (e.g., the first portion 71) of the second actual pattern 7, the second space S7 (or a gap) between most adjacent two of the plurality of portions 7a (e.g., the first portion 71 and the second portion 72), and the second pitch P7 between the plurality of portions 7a (e.g., between the center of the first portion 71 and the center of the second portion 72).

For example, the second height H7 of the first portion 71 of the second actual pattern 7 may be substantially equal to the first height H1 of the first predetermined imaginary portion 31 of the first predetermined pattern 3. The second width W7 of the first portion 71 of the second actual pattern 7 may be substantially equal to the first width W1 of the second predetermined imaginary portion 31 of the first predetermined pattern 3. The second space S7 (or a gap) of the second actual pattern 7 may be substantially equal to the space S1 (or a gap) of the first predetermined pattern 3. The second pitch P7 of the second actual pattern 7 may be substantially equal to the pitch P1 of the first predetermined pattern 3.

In addition, a width of the portion 72 may be equal to or different from the second width W7. A height of the second portion 72 may be equal to or different from the second height H7. Further, a space (or a gap) between the second 72 and the third portion 73 may be equal to or different from the second space S7 (or a gap). A pitch between the center of the second portion 72 and the center of the third portion 73 may be equal to or different from the second pitch P7.

In some embodiments, the first width W5 of the first portion 51 of the first actual pattern 5 of FIG. 13 may be greater than the second width W7 of the first portion 71 of the second actual pattern 7 of FIG. 14A. The first height H5 of the first portion 51 of the first actual pattern 5 of FIG. 13 may be greater than the second height H7 of the first portion 71 of the second actual pattern 7 of FIG. 14A. The first aspect ratio of the first height H5 to the first width W5 of the first actual pattern 5 of FIG. 13 may be less than, equal to or greater than the second aspect ratio of the second height H7 to the second width W7 of the second actual pattern 7 of FIG. 14A. The first space S5 (or a gap) between the first portion 51 and the second portion 52 of the first actual pattern 5 of FIG. 13 may be less than the second space S7 (or a gap) between the first portion 71 and the portion 72 of the second actual pattern 7 of FIG. 14A. The first pitch P5 between the center of the first portion 51 and the center of the second portion 52 of the first actual pattern 5 of FIG. 13 may be equal to the second pitch P7 between the center of the first portion 71 and the center of the second portion 72 of the second actual pattern 7 of FIG. 14A.

Since the portions 5a of the first actual pattern 5 do not tilt, lean or shift during the spinning process and the portions 7a of the second actual pattern 7 do not undergo the spinning process, the portions 7a of the second actual pattern 7 (including the first portion 71, the second portion 72 and the third portion 73) will stand on the on the top surface 201 of the base material 20 more firmly even when the portions 7a of the second actual pattern 7 (including the first portion 71, the second portion 72 and the third portion 73) are disposed at the periphery portion of the base material 20.

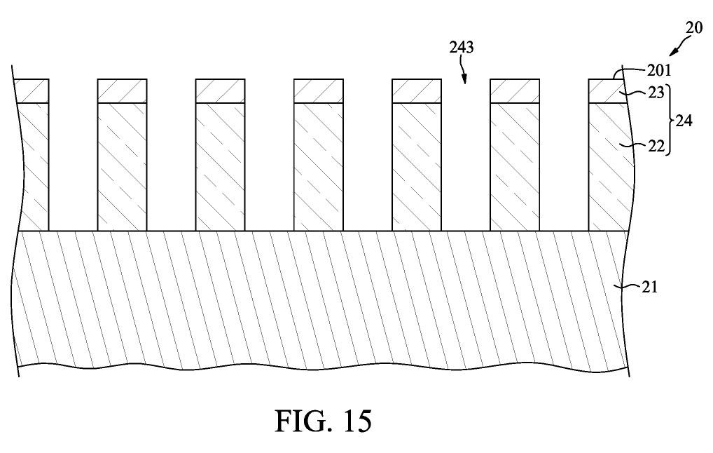

With reference to FIG. 15, at step 908 and step 909, the sacrificial layer 24 (including the carbon layer 22 and the base layer 21) of the base material 20 may be etched to form a plurality of openings 243 by using the second actual pattern 7 of the photoresist layer 50. In some embodiments, the photoresist layer 50 may be removed concurrently. The openings 243 of the sacrificial layer 24 (including the carbon layer 22 and the base layer 21) may correspond to the second space S7 (or a gap) between the portions 7a of the second actual pattern 7 of FIG. 14A. The portions of the sacrificial layer 24 (including the carbon layer 22 and the base layer 21) that are covered by the portions 7a of the second actual pattern 7 of FIG. 14A will not be etched and will remain.

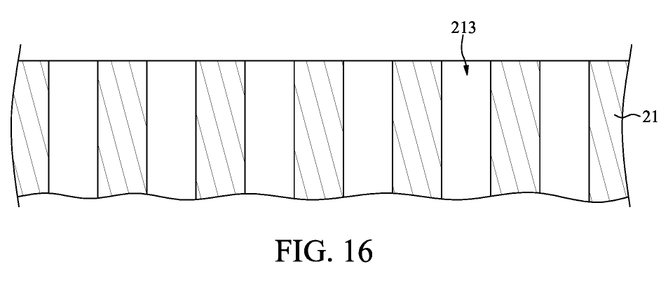

With reference to FIG. 16, the base layer 21 of the base material 20 may be etched to form a plurality of openings 213 by using the pattern of the sacrificial layer 24 (including the carbon layer 22 and the base layer 21). The openings 213 of the base layer 21 may correspond to the openings 243 of the sacrificial layer 24 (including the carbon layer 22 and the base layer 21). The portions of the base layer 21 that are covered by the remaining portions of the sacrificial layer 24 will not be etched and will remain. Then, the sacrificial layer 24 (including the carbon layer 22 and the base layer 21) may be removed by, for example, stripping. Thus, a width of each of the openings 213 of the base layer 21 may be equal to a predetermined width. A space (or a gap) between the openings 213 of the base layer 21 may be equal to a predetermined space (or gap).

One aspect of the present disclosure provides a method of manufacturing a patterned photoresist layer over a base material. The method includes: providing a base material; forming a photoresist layer over the base material, wherein the photoresist layer includes a negative expansion coefficient material; patterning the photoresist layer to form a first actual pattern having a first critical dimension; and applying an energy to the photoresist layer so that the first actual pattern becomes a second actual pattern, wherein the second actual pattern has a second critical dimension different from the first critical dimension of the first actual pattern.

Another aspect of the present disclosure provides a method of manufacturing a patterned photoresist layer over a base material. The method includes: providing a base material; determining a first predetermined pattern; determining a second predetermined pattern according to the first predetermined pattern, wherein a critical dimension of the first predetermined pattern is different from a critical dimension of the second predetermined pattern; forming a photoresist layer over the base material; providing a photomask having a mask pattern corresponding to the second predetermined pattern; patterning the photoresist layer to form a first actual pattern corresponding to the second predetermined pattern through the photomask; and changing the first actual pattern to a second actual pattern corresponding to the first predetermined pattern.

Another aspect of the present disclosure provides method of manufacturing a plurality of openings in a base layer. The method includes: providing a base material including the base layer; forming a photoresist layer over the base material; patterning the photoresist layer to form a first actual pattern; shrinking the first actual pattern to form a second actual pattern; etching the base material to form a plurality of openings by using the second actual pattern; and removing the photoresist layer.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method of manufacturing a patterned photoresist layer over a base material, comprising:
providing a base material;
forming a photoresist layer over the base material, wherein the photoresist layer includes a negative expansion coefficient material;
patterning the photoresist layer to form a first actual pattern having a first critical dimension; and
applying an energy to the photoresist layer so that the first actual pattern becomes a second actual pattern, wherein the second actual pattern has a second critical dimension different from the first critical dimension of the first actual pattern.

2. The method of claim 1, wherein the base material includes a base layer and a sacrificial layer disposed on the base layer.

3. The method of claim 2, wherein the base layer includes silicon (Si).

4. The method of claim 2, wherein the sacrificial layer includes a carbon layer on the base layer and an antireflective coating layer on the carbon layer.

5. The method of claim 1, wherein the photoresist layer has a negative thermal expansion coefficient.

6. The method of claim 1, wherein the second actual pattern shrinks from the first actual pattern.

7. The method of claim 1, wherein the negative expansion coefficient material includes Zr₂WO₄(PO₄)₂ or ZrW₂O₂.

8. The method of claim 1, wherein patterning the photoresist layer to form the first actual pattern includes:
exposing the photoresist layer; and
developing the photoresist layer.

9. The method of claim 8, wherein patterning the photoresist layer to form the first actual pattern further includes:
rinsing the photoresist layer; and
spin drying the photoresist layer.

10. The method of claim 1, wherein the first actual pattern includes a plurality of portions spaced apart from each other.

11. The method of claim 10, wherein the plurality of portions of the first actual pattern are line structures parallel with each other.

12. The method of claim 10, wherein in a cross section, the first critical dimension includes a first width of one of the plurality of portions of the first actual pattern and a first space between most adjacent two of the plurality of portions of the first actual pattern, wherein the first width is greater than the first space.

13. The method of claim 10, wherein the first critical dimension includes a first height of one of the plurality of portions of the first actual pattern and a first width of one of the plurality of portions of the first actual pattern, wherein a first aspect ratio of the first height to the first width is less than 2.7.

14. The method of claim 1, wherein applying the energy to the photoresist layer includes heating the photoresist layer.

15. The method of claim 13, wherein heating the photoresist layer includes heating the photoresist layer to a temperature of 100 ℃ to 120 ℃.

16. The method of claim 1, wherein the second actual pattern includes a plurality of portions spaced apart from each other.

17. The method of claim 16, wherein the plurality of portions of the second actual pattern are line structures parallel with each other.

18. The method of claim 16, wherein in a cross section, the second critical dimension includes a second width of one of the plurality of portions of the second actual pattern and a second space between most adjacent two of the plurality of portions of the second actual pattern, wherein the second width is substantially equal to the second space.

19. The method of claim 16, wherein the second critical dimension includes a second height of one of the plurality of portions of the second actual pattern and a second width of one of the plurality of portions of the second actual pattern, wherein a second aspect ratio of the second height to the second width is greater than 2.8.

20. The method of claim 16, wherein the first actual pattern includes a plurality of portions of the first actual pattern spaced apart from each other, the first critical dimension includes a first height of one of the plurality of portions of the first actual pattern and a first width of one of the plurality of portions of the first actual pattern, the second critical dimension includes a second height of one of the plurality of portions of the second actual pattern and a second width of one of the plurality of portions of the second actual pattern, wherein the first height is greater than the second height, and the first width is greater than the second width.
